(19) United States
(12) Patent Application Publication
(10) Pub. No.: US 2005/0167856 A1
(43) Pub. Date: Aug. 4, 2005

(54) Molded element that consists of brittle-fracture material

(76) Inventors: Martin Sommer, Ockenheim (DE); Christian Dietz, Mainz (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 11/090,231

(22) Filed: Mar. 28, 2005

Related U.S. Application Data
(63) Continuation of application No. 09/780,618, filed on Feb. 12, 2001.

(30) Foreign Application Priority Data
Feb. 11, 2000 (DE) P 100 06 199.0-45

(51) Int. Cl. H01L 21/66

(52) U.S. Cl. 257/787

(57) ABSTRACT

The invention relates to a molded element that consists of brittle-fracture material with at least one opening that is hermetically sealed by a sealing element, whereby the molded element and the sealing element are permanently bonded together.

The invention relates to a molded element that consists of brittle-fracture material, whereby the molded element has at least one opening that is hermetically sealed by a sealing element.

Molded elements that consist of brittle-fracture material, especially glass, are used in the creation of a cavity especially if functional gases or liquids must be protected from contamination or if high transmissivity in the visible spectral range is required. In most cases, the cavity is filled via a fill opening, which in the case of brittle-fracture material should ideally be designed as a circle to avoid stress peaks. In many applications, the fill opening is made as compact as possible for functional and/or aesthetic reasons, and thus in these cases, an additional ventilation opening is often necessary.

After the cavity is filled, the openings are to be sealed, whereby generally the following ideal properties of the seal must be achieved:
Hermetic sealing, especially gastightness (e.g., He-, O₂-, CO₂-tight)
Short processing time
Low costs
No reworking
Thermal expansion coefficient of the sealing material as equal as possible to that of the brittle-fracture material
Sealing material that is chemically inert compared to the filling
Long-term stability of the compound
Mechanical strength of the composite of brittle-fracture material and sealing material
Anti-tamper protection
Avoidance of thermal stresses of the brittle-fracture material, which result in internal stresses in the brittle-fracture material
No inclusion of the ambient atmosphere in the cavity during sealing

It is therefore the object of the invention to provide a molded element that consists of brittle-fracture material, whereby the molded element has at least one opening that is hermetically sealed by a sealing element. In this case, the molded element is to meet the above-mentioned requirements.

The object is achieved according to claim 1 by a molded element that consists of brittle-fracture material, whereby the molded element has at least one opening that is hermetically sealed by a sealing element, and in this case the molded element and sealing element are permanently bonded together.

Since molded elements and sealing elements are permanently bonded together, the above-mentioned requirements can be met.

The inventors have recognized that the permanent bonding of a molded element that consists of brittle-fracture material with a sealing element represents a novel possibility for hermetic sealing of openings in molded elements. In this case, the inventors could show that the above-mentioned stringent requirements can be met in such a sealed molded element.

A molded element according to the invention preferably consists of glass, glass ceramic or ceramic, whereby the molded element preferably is a glass plate.

The sealing element preferably consists of a metal, a metal alloy or a metal composite, whereby the thermal expansion of the molded element and sealing element are preferably matched.

According to another embodiment of the invention, the sealing element can also consist of a brittle-fracture material, especially glass, glass ceramic or ceramic. In particular, if molded elements and sealing elements are made of the same material, the same thermal expansion necessarily results.

Basically, all sealing elements are suitable for hermetic sealing of the opening, which can be permanently bonded with the molded element.

Also, basically no limits are set on the external shape of the sealing element (any sealing-element geometry), whereby platelike, spherical, conical or cylindrical (rodlike) sealing elements have proven especially suitable.

In addition, the molded element preferably has an opening in the form of a through-going cylindrical opening or through-going conical opening, whereby such a molded element also preferably is a glass plate. This opening is preferably a hole.

In this case, it has been shown that for the sealing of a cylindrical opening, especially platelike sealing elements are suitable, whereby the sealing element is bonded with the molded element in such a way that the opening is completely covered by the sealing element.

In the case of the conical opening, especially spherical, conical or cylindrical sealing elements that project at least partially into the opening and are permanently bonded with the molded element are suitable. This makes possible an especially simple bonding of molded elements and sealing elements; tolerances between the opening of the molded element and the sealing element can easily be adjusted.

Molded elements according to the invention are preferably part of laminated glass systems, especially laminated glass systems with electrochromic properties, e.g., laminated glass systems for electrochromic glazings or mirrors.

In another preferred embodiment of the invention, the molded element and/or the sealing element is at least partially coated, especially metal and/or plastic-coated. The bonding can be facilitated by the coating.

In the drawings, embodiments are shown of the molded elements according to the invention that consist of brittle-fracture material with at least one opening, which are hermetically sealed by means of a sealing element, whereby molded elements and sealing elements are permanently bonded together.

Here:

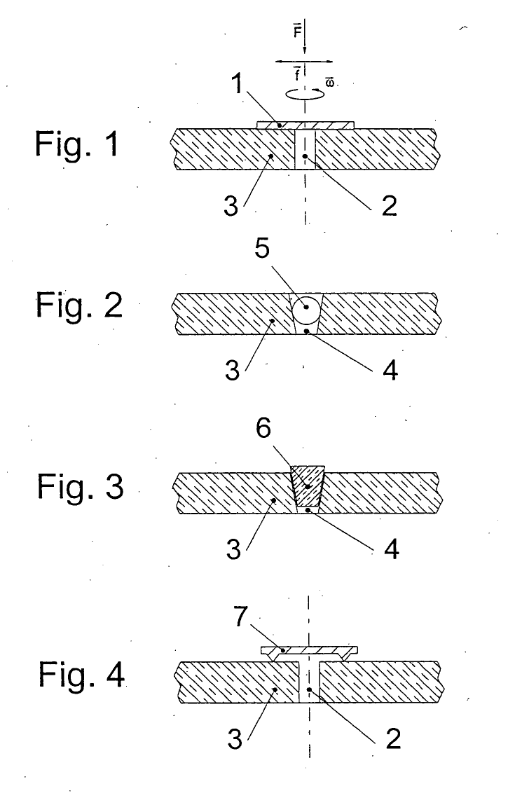

FIG. 1 in a diagrammatic sectional view shows a glass plate with a cylindrical hole that is hermetically sealed by a platelike sealing element

FIG. 2 in a diagrammatic sectional view shows a glass plate with a conical hole that is hermetically sealed by a spherical sealing element

FIG. 3 in a diagrammatic sectional view shows a glass plate with a conical hole that is hermetically sealed by a conical sealing element

FIG. 4 in a diagrammatic sectional view shows a glass plate with a through-going cylindrical opening that is hermetically sealed by a modified, basically small platelike sealing element

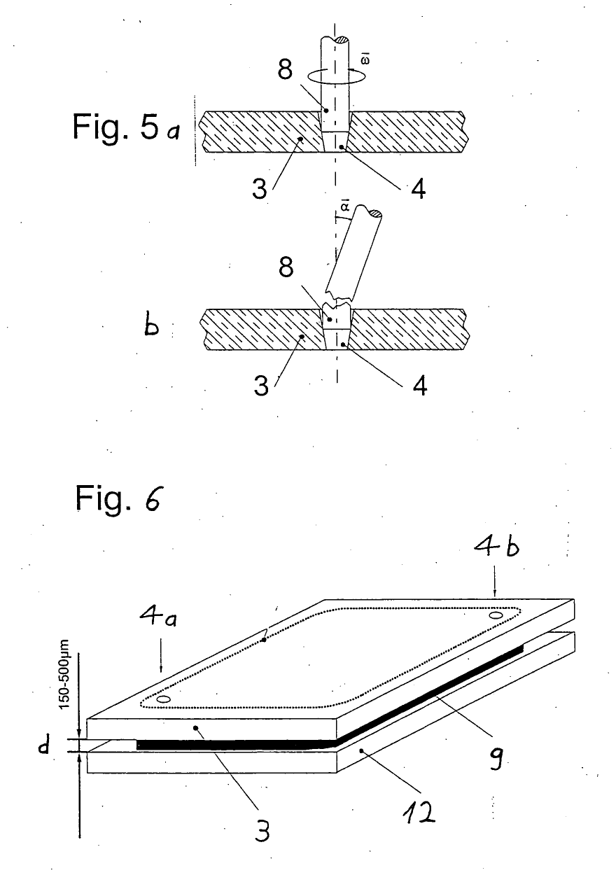

FIG. 5 in a diagrammatic sectional view shows a glass plate with a conical hole that is hermetically sealed by a cylindrical (rodlike) sealing element (a), whereby after the bonding the sealing element is broken off above the bonding (b)

FIG. 6 in a perspective view shows a glass plate with two openings, whereby the glass plate is part of a laminated glass system with electrochromic properties.

A glass plate (3) with a hole-like opening (2) is a component of a cavity (e.g., cover plate). The opening is preferably cylindrical and thus can be produced by a drilling process. According to FIG. 1, the bonding is carried out with a cover plate (1). The latter can consist of metal (e.g., Al, Covar, Cu), coated foils (composite material, e.g., steel with Ti, Au or Pt), ceramics (e.g., Al₂O₃) or glass (also coated glass, e.g., with Al). In this case, glass plate (3) and sealing element (1) are permanently bonded by means of connecting pressure welds, whereby opening (2) is hermetically sealed. In this case, the pressure bonding is carried out, for example, under the action of an external compressive force F perpendicular to the sealing element, whereby the sealing element additionally executes translatory oscillations f and/or rotations ω.

According to FIG. 2, a conical hole (4) and a spherical sealing element (5), which have the advantage of being self centering, are used. The same applies for a molded element of the invention according to FIG. 3, in which a conical sealing element (6) is used. Similar sealing element shapes can be achieved by, for example, applying flame to a rod tip (rounding by drop formation).

In a diagrammatic sectional view, FIG. 4 shows a glass plate (3) with a through-going cylindrical opening (2) that is hermetically sealed by a modified, basically small platelike sealing element (7). The minimized support surface of sealing element (7) via the side edge of opening (2) of glass plate (3) makes possible an especially effective bonding. Thus, for example, tolerances in the area of the side edge of the opening are well balanced. From the minimized support surface, moreover, there results a corresponding increase of the pressure that arises at the bonding point.

FIG. 5 shows a rodlike sealing element (8) that is broken off after the bonding (rotation ω; FIG. 5a) by bending at an angle α (FIG. 5b). Other possibilities for cutting to length are scoring/breaking, cutting, burning, shearing off/pulling off. The possibility of a continuous sealing material readjustment is advantageous compared to intermittent processing with sealing elements that are run in a pick-and-place process (continuous bonding).

FIG. 6 finally shows a laminated glass system with electrochromic properties. The laminated glass system consists of an upper glass plate (3) with a through-going fill opening (4a) and a through-going ventilation opening (4b) in the form of holes and a lower glass plate (12). The two glass plates are held by a sealing and joining material (9) at interval d, preferably 50 to 500 μm, whereby the resulting cavity between the two glass plates can be filled with a corresponding, functional liquid or a gas. After filling, the two openings are hermetically directly sealed according to the invention by a sealing element, whereby glass plate (3) and the respective sealing elements are permanently bonded together.

The permanent, continuous bonding between molded element and sealing element is preferably produced by a connecting pressure weld process that is known per se. Connecting pressure welds are defined in this case as welding with use of force with or without the addition of welding, whereby a locally limited heating makes possible or facilitates the welding. The welding processes that are integrated in turn in it are:

Welding by solid elements, welding by liquid, welding by gas, welding by electrical gas discharge, welding by movement and welding by electric current.

The preferred welding by movement breaks down further into several processes. Thus, in addition to ultrasound welds, cold pressure welds or abrasive welds as well as shock welds are found.

In this case, in particular the cold pressure welds and the abrasive welds show tight process control affinity to the ultrasound welds. They are therefore used in a supporting manner to describe the basic ultrasound weld process.

In the case of cold pressure welds, the joint partners are joined by applying high pressure. The necessary movement consists of significant plastic flow on the part of at least one joining partner.

The abrasive weld, however, is a hot-pressure process. In this case, the frictional force in the joining area is produced by a rotatory relative movement between the joining partners and a joining force that is acting in a perpendicular manner. The necessary bearing pressure can be drastically reduced in comparison to the cold pressure welds because of a plastification of the materials, caused by the frictional heat that is produced in the case of the rotatory relative movement of the welding parts.

In the case of ultrasound welds, the rotatory movement is replaced by a high-frequency mechanical oscillation.

The main processing time for the sealing of an opening (ø<10 mm) with use of the explained technologies is in the range of a few seconds (e.g., ultrasound welds t≈0.5 s). A reworking is not required, since all necessary properties of the bonding are then already achieved directly. A cosmetic reworking is avoided, since the modified area is only slightly larger than the opening itself, and a local constraint is provided by the existing geometry of the seal. The thermal stress in the surrounding area of the bonding is small compared to the thermal processes (laser, solder glass, etc.) In the case of diffusion weld processes, the thermal stress can even be ignored in the ideal case.

Without further elaboration, it is believed that one skilled in the art can, using the preceding description, utilize the present invention to its fullest extent. The following preferred specific embodiments are, therefore, to be construed as merely illustrative, and not limitative of the remainder of the disclosure in any way whatsoever.

In the foregoing and in the following examples, all temperatures are set forth uncorrected in degrees Celsius; and, unless otherwise indicated, all parts and percentages are by weight.

The entire disclosure of all applications, patents and publications, cited above, and of corresponding German application No. 100 06 190.0-45, filed Feb. 11, 2000 is hereby incorporated by reference.

1-10. (canceled)

11. A method of hermetically sealing a molded element that comprises brittle-fracture material with at least one opening comprising inserting a sealing material into the at least one opening and hermetically sealing the opening by a pressure weld.

12. A method according to claim 1, wherein the brittle-fracture material is glass, glass ceramic or ceramic.

13. A method according to claim 1, wherein the sealing material is a metal, a metal alloy or a metal composite.

14. A method according to claim 1, wherein the sealing material is a brittle-fracture material.

15. A method according to claim 1, wherein the sealing material has a plate, spherical, conical or cylindrical shape.

16. A method according to claim 1, wherein the brittle-fracture material is a glass plate, and wherein the at least one opening has the shape of a through-going cylindrical opening or through-going conical opening.

17. A method according to claim 1, wherein the brittle-fracture material and the sealing material are bonded by welding by movement.

18. A method according to claim 1, wherein the brittle-fracture material and/or the sealing material is at least partially coated.

19. A method according to claim 1, wherein the sealing material is glass, glass ceramic or ceramic.

20. A method according to claim 1, wherein the brittle-fracture material and the sealing material are bonded by ultrasound weld, high-frequency weld, rotary weld, friction weld, torsional or orbital weld, cold pressure weld or abrasive weld.

21. A method according to claim 1, wherein the brittle-fracture material and/or the sealing material is at least partially metal- and/or plastic-coated.

22. A method according to claim 1, wherein the brittle-fracture material and the sealing material have the same coefficients of thermal expansion.

23. A method according to claim 1, wherein the brittle-fracture material and the sealing material are made of the same material.

24. A method according to claim 1, wherein the brittle-fracture material has one or two openings.

25. A method according to claim 1, wherein the sealing material is homogeneous in material.

26. A method according to claim 1, wherein the pressure weld contains material only from the brittle-fracture material and/or the sealing material.

27. A method according to claim 1, wherein the sealing material is solid at the time it is permanently bonded together with the brittle-fracture material by a pressure weld.

28. A method according to claim 1, wherein the at least one opening in the brittle-fracture material is to cavity in the brittle-fracture material, which cavity is optionally filled with a gas or liquid.

29. A method according to claim 28, wherein the brittle-fracture material and the sealing material are bonded by a cold pressure weld.

30. A method of hermetically sealing a molded element that comprises brittle-fracture material with at least one opening comprising inserting a sealing material into the at least one opening and hermetically sealing the opening by a diffusion weld.
